(19) United States
(12) Patent Application Publication
(10) Pub. No.: US 2025/0390087 A1
(43) Pub. Date: Dec. 25, 2025

(54) FAULT DIAGNOSIS METHOD FOR TRANSMISSION CHAIN BASED ON JOINT ENTROPY ENHANCED SPARSE LEARNING USING ZERO SEQUENCE CURRENT

(71) Applicant: Hunan University of Science and Technology, Xiangtan (CN)

(72) Inventors: Zhaohua LIU, Xiangtan (CN); Junjie LONG, Xiangtan (CN); Kan LIU, Xiangtan (CN); Yingjie ZHANG, Xiangtan (CN); Hongwen LIU, Xiangtan (CN); Jiongming YANG, Xiangtan (CN); Mingyang LV, Xiangtan (CN); Ming LI, Xiangtan (CN)

(73) Assignee: Hunan University of Science and Technology, Xiangtan (CN)

(21) Appl. No.: 19/228,811

(22) Filed: Jun. 5, 2025

(30) Foreign Application Priority Data
Jun. 24, 2024 (CN) 202410817539.X

(51) Int. Cl. G05B 23/02

(52) U.S. Cl. CPC G05B 23/0205; G06N 3/0455

(57) ABSTRACT

A fault diagnosis method for a transmission chain based on joint entropy enhanced sparse learning using a zero sequence current includes the following steps: data acquisition and preprocessing; establishment of a rotating machinery fault diagnosis model for sparse feature learning of a zero sequence current; and obtaining of a diagnosis result by inputting the preprocessed zero sequence current data to the trained rotating machinery fault diagnosis model. The fault diagnosis method for a transmission chain based on joint entropy enhanced sparse learning using a zero sequence current can extract a weak fault feature in a current signal automatically and efficiently without relying on traditional signal processing techniques and diagnosis experience, and has good robustness for signals containing noise.

### CROSS REFERENCE TO THE RELATED APPLICATIONS

This application is based upon and claims priority to Chinese Patent Application No. 202410817539.X, filed on Jun. 24, 2024, the entire contents of which are incorporated herein by reference.

### TECHNICAL FIELD

The present disclosure relates to the field of fault diagnosis of rotating components, and in particular, to a fault diagnosis method for a transmission chain based on joint entropy enhanced sparse learning using a zero sequence current.

### BACKGROUND

Rotating machinery is a critical component of an industrial transmission system such as rolling bearings and gears, and the safety and reliability of the rotating machinery are of vital importance. However, the rotating machinery is highly prone to faults in severe working environment with high load and high torque. If these faults cannot be found in time, the equipment shutdown time may be prolonged and the maintenance cost may be increased. Also, tremendous economic losses and personnel casualties may be caused. Therefore, accurate and effective fault identification of the rotating machinery is of vital importance for ensuring the safety and reliability of industrial equipment.

In recent years, a lot of researches have been conducted on methods for diagnosing faults of a power transmission system, mainly including methods such as vibration, sound emission, and temperature. At present, a vibratory diagnosis method is mainly used because a vibration signal contains rich fault information. The diagnosis method based on a vibration signal has been studied extensively. However, in practical application, such a method still faces some challenges. First, it is required that a sensor should be mounted on the rotating machinery so as to acquire a vibration signal, leading to high cost. Second, in order to make accurate measurement, the sensor must be closely mounted on the rotating machinery, and due to the limitation of the mounting position, it is hard for the sensor to be applied to the equipment that has been put on production. Even through the sensor is mounted on the equipment, interference may be caused for the system. Furthermore, the sensor itself may malfunction. On the contrary, the diagnosis method based on a current signal does not additional sensor because the current is the most basic electrical quantity in the electromechanical equipment. The stator current of a motor may be directly obtained from a motor control system. Analysis based on the stator current of the motor is a state monitoring method without sensor, which is also a more economical and more reliable method.

The existing current-based fault diagnosis method is based on a single-phase current signal. Due to different initial conditions (phase/amplitude/measurement noise), the information included in the current of each phase may also be different. Therefore, the method based on single-phase current analysis only uses part of the total information of a three-phase system. Nowadays, three-phase rotating motors have been widely applied to wind turbines, automobiles, metallurgical machinery, and other complicated mechanical equipment. Therefore, it is necessary to take quantities of three phases into account in monitoring the states of the three-phase system.

In order to extract a weak fault feature from a current signal and improve the accuracy of diagnosis, various advanced signal processing methods have been adopted to process the current signal to extract an effective feature. However, these methods have limitations in terms of stability and universality. Specifically, most methods are designed based on a plurality of signal preprocessing methods of time domain, frequency domain, and time-frequency domain, requiring a good deal of prior knowledge or diagnostic professional knowledge and reducing the intelligence of diagnosis. Second, the extracted fault feature is extremely sensitive. If the selected feature is not suitable for a new fault diagnosis task, the diagnosis accuracy will decrease significantly. Deep learning (DL) method has powerful capability of automatically learning abstract and useful feature representations, can eliminate the subjectivity and uncertainty of manual selection of fault features, and thus has become the effective means to replace the traditional signal processing and feature extraction techniques. Automatic feature learning has received increasing attention in the fault diagnosis field. For example, the convolutional neural network (CNN) and the autoencoder (AE) have been used for machine state identification and effective current signal processing.

The deep learning method is superior to other most advanced fault detection methods in some applications, but is stilled limited by some challenges in terms of application. The CNN method requires the use of a large number of tagged data sets, which is hard to realize in complex industrial production. In this case, the AE using an unsupervised neural network becomes a better choice. Therefore, to make the most of the unsupervised feature learning capability of the autoencoder, a new deep autoencoder must be developed for feature learning and enhancement so as to realize high accuracy diagnosis.

### SUMMARY

In order to solve the above technical problems, the present disclosure provides a fault diagnosis method for a transmission chain based on joint entropy enhanced sparse learning using a zero sequence current, which has a simple algorithm, good robustness, and high diagnosis accuracy.

The technical solutions adopted by the present disclosure to solve the above technical problems are as follows: a fault diagnosis method for a transmission chain based on joint entropy enhanced sparse learning using a zero sequence current includes the following steps:
step 1, data acquisition and preprocessing: establishing a rotating machinery fault simulation experiment platform, collecting currents of phases A, B, and C of a three-phase motor under different fault conditions of a bearing and a gear in a transmission system, then calculating a zero sequence current of current signals of three phases, and finally preprocessing zero sequence current data;
step 2, establishment of a rotating machinery fault diagnosis model for sparse feature learning of a zero sequence current: establishing the rotating machinery fault diagnosis model, initializing model parameters, fine tuning network parameters layer by layer from top to bottom according to a designed synthetic loss function, completing an entire training process of a network with the purpose of minimizing the synthetic loss function, and retaining an optimal structure of the rotating machinery fault diagnosis model; and
step 3, obtaining of a diagnosis result by inputting the preprocessed zero sequence current data to the trained rotating machinery fault diagnosis model: putting a test sample in the trained network for feature learning, and then inputting the test sample to a Softmax classifier for fault diagnosis.

According to the fault diagnosis method for a transmission chain based on joint entropy enhanced sparse learning using a zero sequence current, in the step 1, first, when a fault occurs on rotating machinery, damage of a bearing rolling body or tooth missing or breakage of a gear component leads to uneven load distribution such that the three phases are not fully symmetrical, resulting in the zero sequence current being not zero; second, the fault of the rotating machinery causes mechanical vibration and shock which are then transferred to a motor stator; in the current signals, the mechanical vibration and shock are manifested as an increase in a zero sequence current component; different faults lead to different zero sequence current phases; therefore, whether the rotating machinery has a fault is determined by monitoring a magnitude of the zero sequence current;
collected instantaneous values of the currents of the phases A, B, and C of the three-phase motor are added together to obtain a zero sequence current signal i_{zsc}(t):

$${i}_{zsc} ( t ) = {i}_{ph\_a} ( t ) + {i}_{ph\_b} ( t ) + {i}_{ph\_c} ( t )$$

where i_{ph_a}(t) represents the instantaneous value of the current of the phase A; i_{ph_b}(t) represents the instantaneous value of the current of the phase B; and i_{ph_c}(t) represents the instantaneous value of the current of the phase C;
the data is augmented by using an overlap sampling method and then normalized; the normalized data is added with a label; and finally, data sets are divided into a training set and a test set.

According to the fault diagnosis method for a transmission chain based on joint entropy enhanced sparse learning using a zero sequence current, in the step 2, the rotating machinery fault diagnosis model for sparse feature learning of a zero sequence current is established to extract a more representative feature from a fault signal;
unlabeled data X=[x₁, x₂, . . . , xₙ]^{T}∈R^{n×m} is given as input data, where n represents a number of samples, m represents a dimension of a sample, and xₙ represents an n^{th} piece of data in X; during encoding, data Zᵢ in a hidden layer is obtained by an encoding function ƒₑ( ); and during decoding, reconstructed data \hat{X} is obtained by a decoder using a mapping function g_{d}( );

$$\{ \begin{matrix}{Z}_{j} = {f}_{e} ( X ) = {σ}_{f} ( WX + b ) \\ \hat{X} = {g}_{d} ( Z ) = {δ}_{g} ( {W}^{′} Z + {b}^{′} )\end{matrix}$$

where σ_{ƒ} and δ_{g} represent nonlinear activation functions during encoding and during decoding, respectively; W represents a weight matrix; W′ represents a derivative of W; b represents a bias matrix; and b′ represents a derivative of b.

According to the fault diagnosis method for a transmission chain based on joint entropy enhanced sparse learning using a zero sequence current, in the step 2, a sparse autoencoder is configured to obtain an optimal parameter ω={W, b, W′, b′} by minimizing an error between the reconstructed data \hat{X} and the input data X, and trained by minimizing a cost function;

$$\begin{matrix}J ( ω ) = {J}_{M S E} ( ω ) + β {J}_{K L} ( r ‖ \hat{r} ) \\ = \frac{1}{n} {\sum }_{i = 1}^{n} ( \frac{1}{2} {‖ {\hat{x}}_{i} - {x}_{i} ‖}^{2} ) \\ + β {\sum }_{j = 1}^{{n}_{s}} ( r log \frac{r}{{\hat{r}}_{j}} + ( 1 - r ) log \frac{1 - r}{1 - {\hat{r}}_{j}} )\end{matrix}$$

where J(ω) represents the cost function; J_{MSE}(ω) represents a reconstruction error; β represents a sparse weight; \hat{x}ᵢ represents an i^{th} reconstructed sample; xᵢ represents an i^{th} original input sample; nₛ represents a number of hidden layers; r represents a sparse parameter; \hat{r}ⱼ represents a sparse parameter of a j^{th} neuron; J_{KL}(r∥\hat{r}) represents a sparse penalty term; and J_{KL}(r∥\hat{r}) is configured to maintain low average activity of hidden neurons to ensure that more features are learned.

According to the fault diagnosis method for a transmission chain based on joint entropy enhanced sparse learning using a zero sequence current, in the step 2, the loss function is improved on the basis of the sparse autoencoder and the synthetic loss function is designed to replace a traditional mean square error, and a specific process is as follows:
first, for the limitations of a traditional reconstruction loss, a joint entropy function is introduced; a joint entropy relates to generalized computing of a similarity between two random variables A=[a₁, a₂, . . . aₙ]^{T} and B=[b₁, b₂, . . . bₙ]^{T}, and thus is used as an indicator for an error between input data and reconstructed data; the joint entropy function is defined as:

$${V}_{σ} ( A , B ) = E [ {κ}_{σ} ( A - B ) ]$$

where K_{σ}( ) represents a kernel function meeting Mercer theory, and E represents an expected value;
an estimated value of the joint entropy is calculated as follows:

$${\hat{V}}_{σ} ( A , B ) = \frac{1}{n} {\sum }_{i = 1}^{n} {κ}_{σ} ( {a}_{i} - {b}_{i} )$$

where aᵢ and bᵢ represent i^{th} pieces of data in A and B, respectively;
Gaussian kernel is Mercer kernel in the joint entropy, and is defined as:

$${κ}_{σ} = \frac{1}{\sqrt{2 π} σ} exp ( - \frac{{( {a}_{i} - {b}_{i} )}^{2}}{2 {σ}^{2}} )$$

where σ represents a kernel size; and
a joint entropy loss function is then designed to replace the traditional mean square error, and is as follows:

$${J}_{MC} ( ω ) = \frac{1}{n} {\sum }_{i = 1}^{n} {κ}_{σ} ( {\hat{x}}_{i} - {x}_{i} ) .$$

According to the fault diagnosis method for a transmission chain based on joint entropy enhanced sparse learning using a zero sequence current, in the step 2, in order to further reinforce feature learning, a nonnegative constraint term is introduced in the cost function, and the cost function with the introduced nonnegative constraint term is expressed as J_{weight}(ω):

$$\begin{matrix}{J}_{weight} ( ω ) = \frac{λ}{2} {\sum }_{l = 1}^{k - 1} {\sum }_{p = 1}^{{m}_{l}} {\sum }_{q = 1}^{{m}_{l - 1}} G ( {W}_{pq}^{l} ) \\ G ( {W}_{pq}^{l} ) = \{ \begin{matrix}{( {W}_{pq}^{l} )}^{2} , & {W}_{pq}^{l} > 0 \\ 0 , & {W}_{pq}^{l} \leq 0\end{matrix}\end{matrix}$$

where G( ) represents a nonnegative constraint function for ensuring that a weight value of a neuron is nonnegative;

$${W}_{pq}^{l}$$

represents a weight between a p^{th} unit of an l^{th} layer and a q^{th} unit of an (l+1)^{th} layer; λ represents a weighting coefficient; k represents a number of network layers; and mₗ represents a number of nodes of the l^{th} layer.

According to the fault diagnosis method for a transmission chain based on joint entropy enhanced sparse learning using a zero sequence current, in the step 2, since the sparse autoencoder is configured to minimize the loss function and the joint entropy is used for calculating a similarity between the input data and the reconstructed data, in order to maximize the joint entropy while minimizing the reconstruction error, a new loss function J_{new}(ω) is designed:

$${J}_{new} ( ω ) = - {J}_{MC} ( ω ) + β {J}_{KL} ( r ‖ \hat{r} ) + λ {J}_{w e i g h t} ( ω )$$

after a model structure is established, the network parameters are initialized; the network parameters are fine tuned layer by layer from top to bottom according to the proposed loss function J_{new}(ω); the entire training process of the network is completed with the purpose of minimizing J_{new}(ω); and the optimal structure of the rotating machinery fault diagnosis model is retained when the training task is finished.

According to the fault diagnosis method for a transmission chain based on joint entropy enhanced sparse learning using a zero sequence current, in the step 3, the Softmax function is expressed as:

$$Softmax ( {z}_{d} ) = \frac{{e}^{{z}_{d}}}{{\sum }_{c = 1}^{C} {e}^{{z}_{c}}}$$

where z_{d} represents an output value of a dₜₕ node; c represents an ordinal number of an output node; C represents a total number of output nodes, namely a number of categories; and the test sample is input to the trained rotating machinery fault diagnosis model for feature learning, and then input to the Softmax for fault diagnosis.

The present disclosure has the following beneficial effects:
1. Since the existing methods based on current cannot provide good performance and have the problems of weak signal amplitudes, low signal to noise ratios, etc., by exploring the fault diagnosis issue of the rotating machinery based on zero sequence current signals, it has been found that compared with a single-phase current, the fault information using the zero sequence current is richer and can be applied to the fault diagnosis of the rotating machinery.
2. The fault diagnosis method for a transmission chain based on joint entropy enhanced sparse learning using a zero sequence current provided in the present disclosure can extract a weak fault feature in a current signal automatically and efficiently without relying on traditional signal processing techniques and diagnosis experience, and has good robustness for signals containing noise.
3. The fault diagnosis method for a transmission chain based on joint entropy enhanced sparse learning using a zero sequence current provided in the present disclosure has the advantages of good robustness and strong generalization capability, and can be applied not only to fault diagnosis of rolling bearings and gears in transmission systems, but also extensively to a range of complex systems such as electromobiles, aviation, and high-speed railways.

### BRIEF DESCRIPTION OF THE DRAWINGS

FIG. 1 is a flow chart of the present disclosure.

FIGS. 2A-2B are time-domain distribution diagram of single-phase currents and zero sequence currents under a healthy condition and a fault condition of rotating machinery.

FIG. 3 is a schematic diagram of a rotating machinery fault diagnosis model.

FIG. 4 is a schematic diagram showing experimental results with a bearing data set.

FIG. 5 is a schematic diagram showing experimental results with a gear data set.

### DETAILED DESCRIPTION OF THE EMBODIMENTS

The present disclosure is further described below with reference to the accompanying drawings and embodiments.

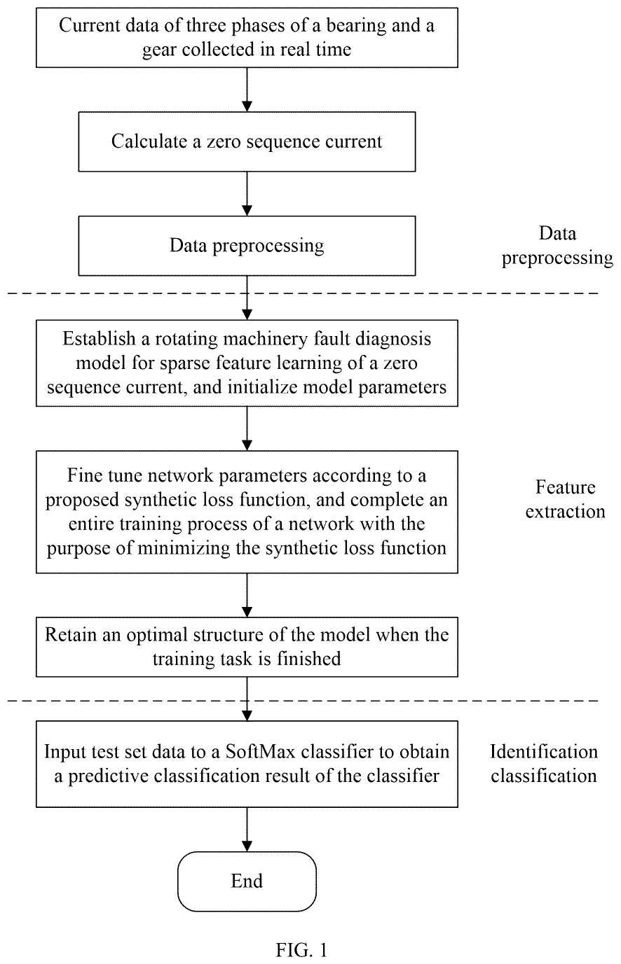

As shown in FIG. 1, a fault diagnosis method for a transmission chain based on joint entropy enhanced sparse learning using a zero sequence current includes the following steps.

In the step 1, data acquisition and preprocessing: a rotating machinery fault simulation experiment platform is established; currents of phases A, B, and C of a three-phase motor under different fault conditions of a bearing and a gear in a transmission system are collected; then a zero sequence current of current signals of three phases is calculated; and zero sequence current data is finally preprocessed.

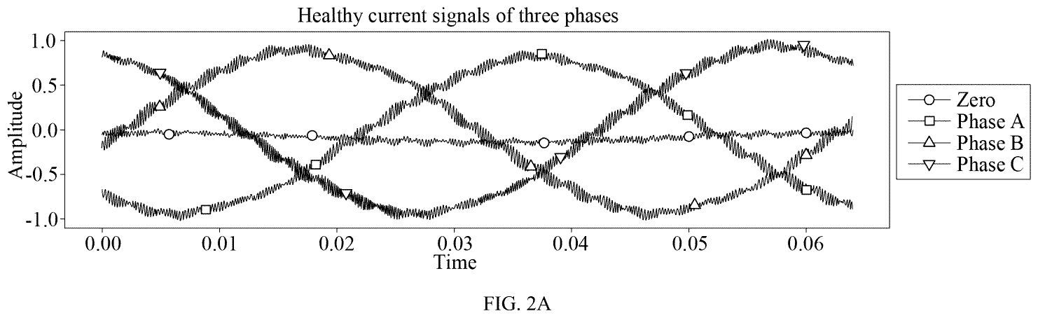

First, when a fault occurs on rotating machinery, damage of a bearing rolling body or tooth missing or breakage of a gear component will lead to uneven load distribution such that the three phases are not fully symmetrical, resulting in the zero sequence current being not zero. Second, the fault of the rotating machinery will cause mechanical vibration and shock which are then transferred to a motor stator. In the current signals, the mechanical vibration and shock will be manifested as an increase in a zero sequence current component. Different faults may also lead to different zero sequence current phases. As shown in FIGS. 2A-2B, therefore, whether the rotating machinery has a fault may be determined by monitoring a magnitude of the zero sequence current. The upper chart of FIGS. 2A-2B show the current signals of the three phases and the zero sequence current signal when the bearing is in the healthy state, and the lower chart shows the zero sequence current signals when faults occur on an inner race, an outer race, and a ball.

The collected instantaneous values of the currents of the phases A, B, and C of the three-phase motor are added together to obtain a zero sequence current signal i_{zsc}(t).

$${i}_{zsc} ( t ) = {i}_{ph \_ a} ( t ) + {i}_{ph \_ b} ( t ) + {i}_{ph \_ c} ( t )$$

where i_{ph_a}(t) represents the instantaneous value of the current of the phase A; i_{ph_b}(t) represents the instantaneous value of the current of the phase B; and i_{ph_c}(t) represents the instantaneous value of the current of the phase C.

The data is augmented by using an overlap sampling method and then normalized. The normalized data is added with a label, and finally, data sets are divided into a training set and a test set.

In the step 2, establishment of a rotating machinery fault diagnosis model for sparse feature learning of a zero sequence current: the rotating machinery fault diagnosis model is established; model parameters are initialized; network parameters are fine tuned layer by layer from top to bottom according to a designed synthetic loss function; an entire training process of a network is completed with the purpose of minimizing the synthetic loss function; and an optimal structure of the rotating machinery fault diagnosis model is retained.

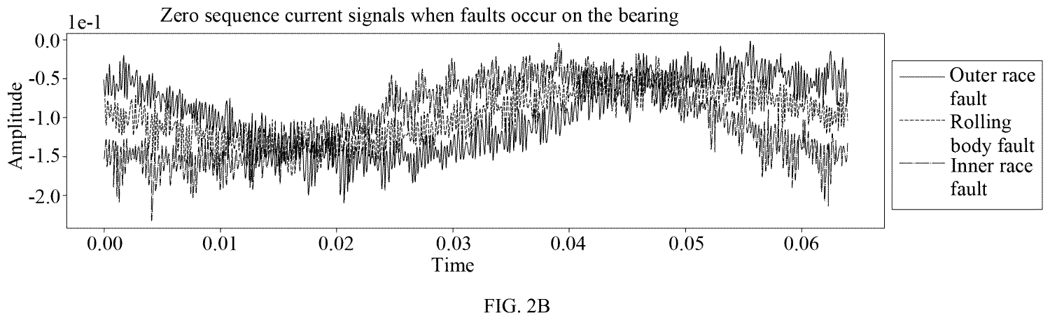

As shown in FIG. 3, the rotating machinery fault diagnosis model for sparse feature learning of a zero sequence current is established to extract a more representative feature from a fault signal.

Unlabeled data X=[x₁, x₂, . . . , xₙ]^{T}∈R^{n×m} is given as input data, where n represents a number of samples, m represents a dimension of a sample, and xₙ represents an n^{th} piece of data in X; during encoding, data Zᵢ in a hidden layer is obtained by an encoding function ƒₑ( ); and during decoding, reconstructed data \hat{X} is obtained by a decoder using a mapping function g_{d}( );

$$\{ \begin{matrix}{Z}_{i} = {f}_{e} ( X ) = {σ}_{f} ( WX + b ) \\ \hat{X} = {g}_{d} ( Z ) = {δ}_{g} ( {W}^{′} Z + {b}^{′} )\end{matrix}$$

where σ_{ƒ} and β_{g} represent nonlinear activation functions during encoding and during decoding, respectively; W represents a weight matrix; W′ represents a derivative of W; b represents a bias matrix; and b′ represents a derivative of b.

A sparse autoencoder is configured to obtain an optimal parameter ω={W, b, W′, b′} by minimizing an error between the reconstructed data \hat{X} and the input data X, and trained by minimizing a cost function;

$$J ( ω ) = \text{} {J}_{MSE} ( ω ) + β {J}_{KL} ( r ‖ \hat{r} ) = \frac{1}{n} {\sum }_{i = 1}^{n} ( \frac{1}{2} {‖ {\hat{x}}_{i} - {x}_{i} ‖}^{2} ) + β {\sum }_{j = 1}^{{n}_{s}} ( r log \frac{r}{{\hat{r}}_{j}} + ( 1 - r ) log \frac{1 - r}{1 - {\hat{r}}_{j}} )$$

where J(ω) represents the cost function; J_{MSE}(ω) represents a reconstruction error; β represents a sparse weight; \hat{x}ᵢ represents an i^{th} reconstructed sample; xᵢ represents an i^{th} original input sample; nₛ represents a number of hidden layers; r represents a sparse parameter; \hat{r}ⱼ represents a sparse parameter of a j^{th} neuron; J_{KL}(r∥\hat{r}) represents a sparse penalty term; and J_{KL}(r∥\hat{r}) is configured to maintain low average activity of hidden neurons to ensure that more features are learned.

In the sparse autoencoder, the mean square error is conventionally regarded as a loss function. However, this lacks robustness for feature learning. In order to improve the capability of the sparse autoencoder to extract features, the loss function is improved on the basis of the sparse autoencoder and the synthetic loss function is designed to replace the traditional mean square error, and a specific process is as follows:
first, for the limitations of a traditional reconstruction loss, a joint entropy function is introduced; a joint entropy relates to generalized computing of a similarity between two random variables A=[a₁, a₂, . . . aₙ]^{T} and B=[b₁, b₂, . . . bₙ]^{T}, and thus is used as an indicator for an error between input data and reconstructed data; the joint entropy function is defined as:

$${V}_{σ} ( A , B ) = E [ {κ}_{σ} ( A - B ) ]$$

where K_{σ}( ) represents a kernel function meeting Mercer theory, and E represents an expected value;
an estimated value of the joint entropy is calculated as follows:

$${\hat{V}}_{σ} ( A , B ) = \frac{1}{n} {\sum }_{i = 1}^{n} {κ}_{σ} ( {a}_{i} - {b}_{i} )$$

where aᵢ and bᵢ represent i^{th} pieces of data in A and B, respectively;

Gaussian kernel is Mercer kernel in the joint entropy, and is defined as:

$${κ}_{σ} = \frac{1}{\sqrt{2 π} σ} exp ( - \frac{{( {a}_{i} - {b}_{i} )}^{2}}{2 {σ}^{2}} )$$

where σ represents a kernel size; and
a joint entropy loss function is then designed to replace the traditional mean square error, and is as follows:

$${J}_{MC} ( ω ) = \frac{1}{n} {\sum }_{i = 1}^{n} {κ}_{σ} ( {\hat{x}}_{i} - {x}_{i} ) .$$

In order to further reinforce feature learning, a nonnegative constraint term is introduced in the cost function. This makes the model parameters sparser so that a more representative feature can be learned from high dimensional data. The cost function with the introduced nonnegative constraint term is expressed as J_{weight}(ω):

$${J}_{weight} ( ω ) = \frac{λ}{2} {\sum }_{l = 1}^{k - 1} {\sum }_{p = 1}^{{m}_{l}} {\sum }_{q = 1}^{{m}_{l - 1}} G ( {W}_{pq}^{l} )$$

$$G ( {W}_{pq}^{l} ) = \{ \begin{matrix}{( {W}_{pq}^{l} )}^{2} , & {W}_{pq}^{l} > 0 \\ 0 , & {W}_{pq}^{l} \leq 0\end{matrix}$$

where G( ) represents a nonnegative constraint function for ensuring that a weight value of a neuron is nonnegative;

$${W}_{pq}^{l}$$

represents a weight between a p^{th} unit of an l^{th} layer and a q^{th} unit of an (l+1)^{th} layer; λ represents a weighting coefficient; k represents a number of network layers; and mₗ represents a number of nodes of the l^{th} layer.

Since the sparse autoencoder is configured to minimize the loss function and the joint entropy is used for calculating a similarity between the input data and the reconstructed data, in order to maximize the joint entropy while minimizing the reconstruction error, a new loss function J_{new}(ω) is designed:

$${J}_{new} ( ω ) = - {J}_{MC} ( ω ) + β {J}_{KL} ( r ‖ \hat{r} ) + λ {J}_{weight} ( ω )$$

After a model structure is established, the network parameters are initialized; the network parameters are fine tuned layer by layer from top to bottom according to the proposed loss function J_{new}(ω); the entire training process of the network is completed with the purpose of minimizing J_{new}(ω); and the optimal structure of the rotating machinery fault diagnosis model is retained when the training task is finished.

In the step 3, obtaining of a diagnosis result by inputting the preprocessed zero sequence current data to the trained rotating machinery fault diagnosis model: a test sample is put in the trained network for feature learning, and then input to a Softmax classifier for fault diagnosis.

$$Softmax ( {z}_{d} ) = \frac{{e}^{{z}_{d}}}{{\sum }_{c = 1}^{C} {e}^{{z}_{c}}}$$

where z^{d} represents an output value of a d^{th} node; c represents an ordinal number of an output node; C represents a total number of output nodes, namely a number of categories; and the test sample is input to the trained rotating machinery fault diagnosis model for feature learning, and then input to the Softmax for fault diagnosis.

In order to verify the effectiveness of the proposed method, the proposed method is compared with other methods. The methods to be compared are as follows:
(1) SP-CESL: As with conventional current diagnostics, single-phase currents are directly used as inputs to the CESL;
(2) SC-CESL: The three-phase currents are first time-shifted and synchronized, then integrated and squared to obtain the current residual signal. Finally, the current residual signal is fed into the CESL;
(3) ZS-SAE: It adopts ZSC data as input to a standard SAE. The parameters are consistent with the proposed method;
(4) ZS-SVM: It adopts the ZSC data and then use SVM for fault classification;
(5) ZS-CNN: zero sequence current data is used, and then a CNN is used for subsequent feature extraction and classification; and
(6) VS-CESL: vibration signal data is used as an input to the proposed model.

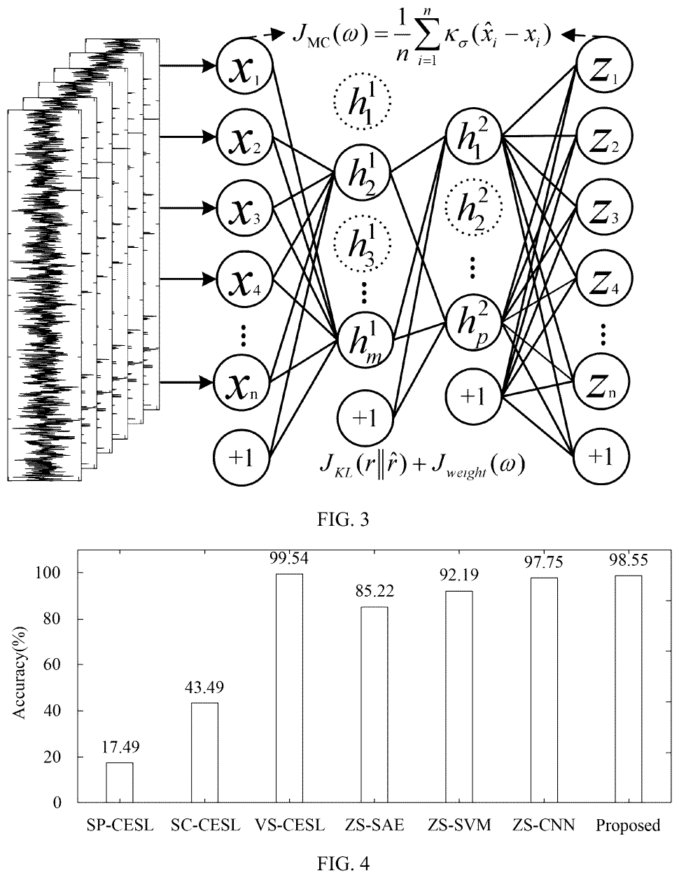

Meanwhile, experiment results with fault data sets of a bearing and a gear are given. The diagnosis results of a bearing fault are as shown in FIG. 4. In the experiment on the bearing fault, it can be seen that the accuracy of the proposed method is 98.55%, which is obviously higher than those of other methods.

TABLE 1
Comparison between the Proposed Method
and Related Works with Bearing Data Set

| Method | | Standard | |
|---|---|---|---|
| Comparison | Accuracy (%) | Deviation | Time (s) |
| SP-CESL | 17.49% | 1.53 | 46.57 |
| SC-CESL | 43.49% | 1.48 | 56.84 |
| VS-CESL | 99.54% | 0.18 | 57.34 |
| ZS-SAE | 85.22% | 0.36 | 51.12 |
| ZS-SVM | 92.19% | 0.86 | 26.65 |
| ZS-CNN | 97.75% | 0.48 | 141.22 |
| Proposed | 98.55% | 0.12 | 59.60 |

The third column in Table 1 shows the standard deviations of the accuracy rates of the models. From the data, the standard deviation of the proposed method of the present disclosure is minimum, i.e., 0.12, which is less than those of other methods. The fourth column in Table 1 shows average calculation times. The average calculation time of the proposed method is 59.6 seconds, which can meet the requirement on the spot in industrial applications. Generally, compared with other methods, the proposed method achieves significant effects and has the best diagnostic performance.

Specifically:

### 1) Advantages of Zero Sequence Current

a) In the methods based on current, if only the single-phase current is used, the accuracy of fault diagnosis by the SP-CESL method is 17.49%. However, if the zero sequence current is used as the input to the network, the accuracy may increase significantly. This is because the single-phase current cannot obviously describe a mechanical fault, and the zero sequence current contains all the information of the currents of three phases and thus is more suitable for the diagnosis of the mechanical fault.
b) if a stator synchronizing current integration method is adopted, although the SC-CESL model has noise removed to a certain extent, the fault information is still not sensitive enough and good diagnostic performance cannot be performed.
b) Compared with the method based on a vibration signal, the accuracy of the VS-CESL method reaches 99.54%, which is slightly higher than the method proposed in the present disclosure, but this method has limitations in practical application. Therefore, the method proposed in the present disclosure has better performance.

### 2) Advantages of Proposed Models

a) compared with standard SAE, the method proposed in the present disclosure has better feature extraction capability. This attributes to the designed synthetic loss function having better robustness and adaptability for abnormal values and background noise of motor current signals. In particular, the proposed joint entropy loss item is insensitive to complicated background noise, and the robust fault features extracted from the signals are more reliable. Second, the introduced nonnegative constraint term can further enhance the sparsity such that the model concentrates more on learning of positive features.
b) Compared with the CNN method, the CNN is more sensitive to data and may be effectively trained with a lot of labeled data, thus leading to a great fluctuation in the calculation result. Meanwhile, the calculation complexity is relatively high, which leads to long calculation time and is not conducive to practical application. The method proposed in the present disclosure can achieve unsupervised learning and can learn effective feature representations from a lot of unlabeled data.
c) Compared with the machine learning method requiring manual extraction of features, the deep learning method has better diagnostic performance. This is because the deep learning method can adaptively learn representative features from input data, thereby reducing expert experience and manual intervention, and has high generalization performance.

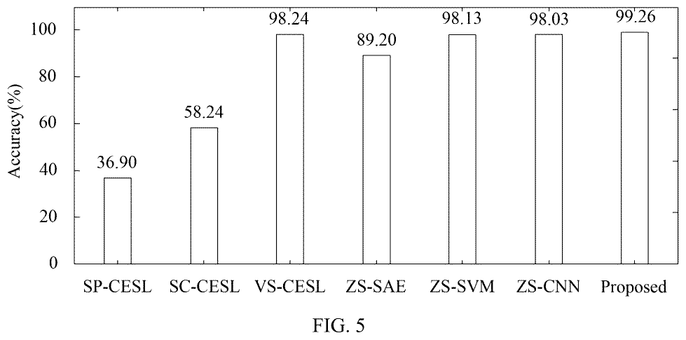

The diagnosis results of a gear fault are as shown in FIG. 5. Compared with the competitors, the performance of the model proposed in the present disclosure is still the best, and the average accuracy reaches 99.26%.

TABLE 2
Comparison between the Proposed Method
and Related Works with Gear Data Set

| Method | | Standard | |
|---|---|---|---|
| Comparison | Accuracy (%) | Deviation | Time (s) |
| SP-CESL | 36.90% | 1.22 | 60.31 |
| SC-CESL | 58.24% | 1.51 | 39.01 |
| VS-CESL | 98.24% | 0.65 | 28.73 |
| ZS-SAE | 89.20% | 1.63 | 38.98 |
| ZS-SVM | 98.13% | 0.39 | 26.56 |
| ZS-CNN | 98.03% | 1.76 | 102.82 |
| Proposed | 99.26% | 0.40 | 59.50 |

As can be seen from Table 2, the zero sequence current contains more fault information than the single-phase current, and the diagnostic accuracy thereof is even not lower than that of the vibration signal. Therefore, the zero sequence current is more suitable for the fault diagnosis of the rotating machinery.

To sum up, in the present disclosure, the zero sequence current is used for the fault diagnosis of the rotating machinery. A fault diagnosis method for a transmission chain based on joint entropy enhanced sparse learning using a zero sequence current is provided, which can extract a weak fault feature in a current signal automatically and efficiently and realize high accuracy fault diagnosis of the rotating machinery. By analyzing the fault mechanism of the zero sequence current, it has been found that compared with a single-phase current, the fault information using the zero sequence current is richer and can be applied to the fault diagnosis of the rotating machinery. Second, a joint entropy enhanced sparse feature learning method is designed, which can effectively extract a fault feature without manual feature extraction and has good robustness for signals containing noise. Compared with the prior art, the method provided in the present disclosure has high generalization performance and robustness, which provides a highly effective approach for finishing the fault diagnosis task of the rotating machinery and has good application prospects.

What is claimed is:

1. A fault diagnosis method for a transmission chain based on joint entropy enhanced sparse learning using a zero sequence current, comprising the following steps:
step 1, data acquisition and preprocessing: collecting a current of a phase A, a current of a phase B, and a current of a phase C of a three-phase motor under different fault conditions of a bearing and a gear in a transmission system, then calculating the zero sequence current of current signals of three phases, and finally preprocessing zero sequence current data to obtain preprocessed zero sequence current data;
step 2, establishment of a rotating machinery fault diagnosis model for sparse feature learning of the zero sequence current: establishing the rotating machinery fault diagnosis model, initializing model parameters, fine tuning network parameters layer by layer from top to bottom according to a designed synthetic loss function, completing an entire training process of a network with a purpose of minimizing the designed synthetic loss function, and retaining an optimal structure of the rotating machinery fault diagnosis model to obtain a trained rotating machinery fault diagnosis model;
wherein in the step 2, the designed synthetic loss function is improved on a basis of a sparse autoencoder and the designed synthetic loss function is designed to replace a traditional mean square error, and a process is as follows:
first, for limitations of a traditional reconstruction loss, introducing a joint entropy function, wherein a joint entropy is generalized computing of a similarity between two random variables A=[a₁, a₂, . . . aₙ]^{T} and B=[b₁, b₂, . . . bₙ]^{T}, and the joint entropy is configured as an indicator for an error between input data and reconstructed data; and the joint entropy function is defined as:
$${V}_{σ} ( A , B ) = E [ {κ}_{σ} ( A - B ) ]$$
wherein K_{σ}( ) represents a kernel function meeting Mercer theory, and E represents an expected value;
calculating an estimated value of the joint entropy as follows:
$${\hat{V}}_{σ} ( A , B ) = \frac{1}{n} {\sum }_{i = 1}^{n} {κ}_{σ} ( {a}_{i} - {b}_{i} )$$
wherein aᵢ and bᵢ represent i^{th} pieces of data in A and B, respectively;
Gaussian kernel is Mercer kernel in the joint entropy, and is defined as:
$${κ}_{σ} = \frac{1}{\sqrt{2 π} σ} exp ( - \frac{{( {a}_{i} - {b}_{i} )}^{2}}{2 {σ}^{2}} )$$
wherein σ represents a kernel size;
designing a joint entropy loss function to replace the traditional mean square error wherein the joint entropy loss function is expressed as follows:
$${J}_{M C} ( ω ) = \frac{1}{n} {\sum }_{i = 1}^{n} {κ}_{σ} ( {\hat{x}}_{i} - {x}_{i} )$$
in order to further reinforce feature learning, introducing a nonnegative constraint term in a cost function, wherein the cost function with the nonnegative constraint term is expressed as J_{weight}(ω):
$${J}_{weight} ( ω ) = \frac{λ}{2} {\sum }_{l = 1}^{k - 1} {\sum }_{p = 1}^{{m}_{l}} {\sum }_{q = 1}^{{m}_{l - 1}} G ( {W}_{pq}^{l} )$$
$$G ( {W}_{pq}^{l} ) = \{ \begin{matrix}{( {W}_{pq}^{l} )}^{2} , & {W}_{pq}^{l} > 0 \\ 0 , & {W}_{pq}^{l} \leq 0\end{matrix}$$
wherein G( ) represents a nonnegative constraint function for ensuring that a weight value of a neuron is nonnegative;
$${W}_{pq}^{l}$$
represents a weight between a p^{th} unit of an l^{th} layer and a q^{th} unit of an (l+1)^{th} layer; λ represents a weighting coefficient; k represents a number of network layers; and mₗ represents a number of nodes of the l^{th} layer;
since the sparse autoencoder is configured to minimize the designed synthetic loss function, and the joint entropy is configured for calculating a similarity between the input data and the reconstructed data, in order to maximize the joint entropy while minimizing a reconstruction error, a new loss function J_{new}(ω) is designed:
$${J}_{new} ( ω ) = - {J}_{MC} ( ω ) + β {J}_{KL} ( r ‖ \hat{r} ) + λ {J}_{weight} ( ω )$$
after a model structure is established, the network parameters are initialized; the network parameters are fine tuned layer by layer from top to bottom according to the new loss function J_{new}(ω); the entire training process of the network is completed with a purpose of minimizing J_{new}(ω) to obtain a trained network; and the optimal structure of the rotating machinery fault diagnosis model is retained when a training task is finished; and
step 3, obtaining a diagnosis result by inputting the preprocessed zero sequence current data to the trained rotating machinery fault diagnosis model: putting a test sample in the trained network for feature learning, and then inputting the test sample to a Softmax classifier for fault diagnosis.

2. The fault diagnosis method for the transmission chain based on the joint entropy enhanced sparse learning using the zero sequence current according to claim 1, wherein the step 1 comprises monitoring a magnitude of the zero sequence current to determine whether a rotating machinery has a fault, wherein when the fault occurs on the rotating machinery, a damage of a bearing rolling body or tooth missing or breakage of a gear component leads to uneven load distribution such that the three phases are not fully symmetrical, making the zero sequence current not zero; the fault of the rotating machinery causes mechanical vibration and shock, wherein the mechanical vibration and the shock are then transferred to a motor stator; in the current signals, the mechanical vibration and the shock are manifested as an increase in a zero sequence current component; and different faults lead to different zero sequence current phases;
collecting and adding an instantaneous value of the current of the phase A, an instantaneous value of the current of the phase B, and an instantaneous value of the current of the phase C of the three-phase motor together to obtain a zero sequence current signal i_{zsc}(t):
$${i}_{zsc} ( t ) = {i}_{ph \_ a} ( t ) + {i}_{ph \_ b} ( t ) + {i}_{ph \_ c} ( t )$$
wherein i_{ph_a}(t) represents the instantaneous value of the current of the phase A; i_{ph_b}(t) represents the instantaneous value of the current of the phase B; and i_{ph_c}(t) represents the instantaneous value of the current of the phase C; and
augmenting the zero sequence current data by using an overlap sampling method and performing normalization to obtain normalized data; adding a label to the normalized data; and dividing data sets into a training set and a test set.

3. The fault diagnosis method for the transmission chain based on the joint entropy enhanced sparse learning using the zero sequence current according to claim 2, wherein the step 2 comprises establishing the rotating machinery fault diagnosis model for the sparse feature learning of the zero sequence current to extract a more representative feature from a fault signal;
giving unlabeled data X=[x₁, x₂, . . . , xₙ]^{T}∈R^{n×m} as the input data, wherein n represents a number of samples, m represents a dimension of a sample, and xₙ represents an n^{th} piece of data in X; during encoding, data Zᵢ in a hidden layer is obtained by an encoding function ƒₑ( ); and during decoding, the reconstructed data \hat{X} is obtained by a decoder using a mapping function g_{d}( );
$$\{ \begin{matrix}{Z}_{i} = {f}_{e} ( X ) = {σ}_{f} ( WX + b ) \\ \hat{X} = {g}_{d} ( Z ) = {δ}_{g} ( {W}^{′} Z + {b}^{′} )\end{matrix}$$
wherein σ_{ƒ} and δ_{g} represent nonlinear activation functions during encoding and during decoding, respectively; W represents a weight matrix; W′ represents a derivative of W; b represents a bias matrix; and b′ represents a derivative of b.

4. The fault diagnosis method for the transmission chain based on the joint entropy enhanced sparse learning using the zero sequence current according to claim 3, wherein the step 2 comprises obtaining an optimal parameter ω={W, b, W′, b′} by minimizing the error between the reconstructed data \hat{X} and the input data X, wherein a training process is achieved by minimizing the cost function;
$$J ( ω ) = {J}_{MSE} ( ω ) + β {J}_{KL} ( r ‖ \hat{r} ) = \frac{1}{n} {\sum }_{i = 1}^{n} ( \frac{1}{2} {‖ {\hat{x}}_{i} - {x}_{i} ‖}^{2} ) + β {\sum }_{j = 1}^{{n}_{s}} ( r log \frac{r}{{\hat{r}}_{j}} + ( 1 - r ) log \frac{1 - r}{1 - {\hat{r}}_{j}} )$$
wherein J(ω) represents the cost function; J_{MSE}(ω) represents the reconstruction error; β represents a sparse weight; \hat{x}ᵢ represents an i^{th} reconstructed sample; xᵢ represents an i^{th} original input sample; nₛ represents a number of hidden layers; r represents a sparse parameter; \hat{r}ⱼ represents a sparse parameter of a j^{th} neuron; J_{KL}(r∥\hat{r}) represents a sparse penalty term; and J_{KL}(r∥\hat{r}) is configured to maintain low average activity of hidden neurons to ensure that more features are learned.

5. The fault diagnosis method for the transmission chain based on the joint entropy enhanced sparse learning using the zero sequence current according to claim 1, wherein in the step 3, a Softmax function is expressed as:
$$Softmax ( {z}_{d} ) = \frac{{e}^{{z}_{d}}}{{\sum }_{c = 1}^{C} {e}^{{z}_{c}}}$$
wherein z_{d} represents an output value of a d^{th} node; c represents an ordinal number of an output node; C represents a total number of output nodes, namely a number of categories; and the test sample is input to the trained rotating machinery fault diagnosis model for feature learning, and then input to the Softmax classifier for the fault diagnosis.
